(19) United States
(12) Patent Application Publication
(10) Pub. No.: US 2008/0296704 A1
(43) Pub. Date: Dec. 4, 2008

(54) SEMICONDUCTOR DEVICE AND MANUFACTURING METHOD THEREOF

(75) Inventor: Ryo WAKABAYASHI, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/132,999

(22) Filed: Jun. 4, 2008

(30) Foreign Application Priority Data
Jun. 4, 2007 (JP) 2007-148089

(51) Int. Cl. H01L 29/78; H01L 21/425

(52) U.S. Cl. 257/410; 438/527; 257/E29.255; 257/E21.473

(57) ABSTRACT

Top and bottom surfaces of a gate insulating film are terminated with fluorine atoms and the top surface of the gate insulating film is then etched. New dangling bonds are formed on the top surface of the gate insulating film. Such new dangling bonds are terminated with nitrogen atoms. A semiconductor device is thus obtained that has a silicon substrate and a gate insulating film formed on the silicon substrate and that almost all dangling bonds on the top surface of the gate insulating film are terminated with nitrogen atoms and almost all dangling bonds on the bottom surface contacting the silicon substrate are terminated with fluorine atoms.

### TECHNICAL FIELD

The present invention relates to a semiconductor device and a manufacturing method thereof, and, more particularly relates to a semiconductor device that has a gate insulating film containing nitrogen and a manufacturing method thereof.

### BACKGROUND OF THE INVENTION

Recently, dual gate CMOS transistors have been usually utilized because of semiconductor devices with higher performance and reduced drive voltages. In the dual gate configuration, a gate electrode containing N-type polysilicon to which an N-type impurity (phosphorous, etc.) is introduced is used for the gate electrode of an N-channel transistor. A gate electrode containing P-type polysilicon to which a P-type impurity (boron, etc.) is introduced is used for a P-channel transistor.

If a thermal load is applied to the dual gate CMOS transistor during steps after the gate electrodes are formed, boron in the gate electrode of the PMOS transistor can pass through a gate insulating film made of a silicon oxide film to diffuse in a silicon substrate (n-well), resulting in a phenomenon that adversely affects electric characteristics of the transistor (boron leakage).

To deal with the problem, a nitriding treatment such as a plasma nitriding is performed after the silicon oxide film is formed to change the silicon oxide film to a silicon oxynitride film for using as the gate insulating film. Diffusion of boron from the gate electrode to the silicon substrate is thus suppressed (see Japanese Patent Application Laid-open Nos. 2001-291865 and 2005-150285).

However, the nitriding treatment can nitride the interface with the silicon substrate or the silicon substrate itself, as well as the surface of the silicon oxide film. That can lead to deteriorated transistor characteristics including high interface state and increased on resistance. This problem becomes serious as the gate insulating film is thinner. In particular, if EOT (Equivalent Oxide Thickness) is equal to or less than 2.0 nm, the interface state density and plus charge in the gate insulating film are increased.

To solve the above problem, Japanese Patent Application Laid-open No. 2001-291865 proposes the method that in the gate insulating film containing silicon, oxygen, and nitrogen as components, the nitrogen density is increased on the surface and decreased on the interface with the silicon substrate. Further, it is also proposed that after the polysilicon film for gate electrode is formed (or after polysilicon film is processed in a desired pattern), halogen (fluorine, etc.) ions are implanted in the gate insulating film to suppress deteriorations in the interface caused by introduction of nitrogen atoms.

However, according to the method of Japanese Patent Application Laid-open No. 2001-291865, the nitriding treatment is performed without terminating dangling bonds on the interface between the gate insulating film and the silicon substrate. Some of the dangling bonds can be terminated with nitrogen atoms. Nitrogen in the gate insulating film is moved toward the substrate because of the thermal treatment at the time of forming the polysilicon film, which is problematic especially when the gate insulating film is thin.

According to the method of Japanese Patent Application Laid-open No. 2001-291865, after the polysilicon film (gate electrode) is formed, fluorine is introduced via the resultant polysilicon film. Therefore, termination with fluorine can be insufficient near channels.

### SUMMARY OF THE INVENTION

The present invention has been achieved to solve the above problems, and an object of the present invention is to provide a semiconductor device that suppresses boron leakage from a gate electrode, an increase in interface state density, and generation of plus charge in a gate insulating film even if the film becomes thinner, and its manufacturing method.

The semiconductor device according to the present invention includes: a silicon substrate; and a gate insulating film formed on the silicon substrate, wherein almost all dangling bonds on a top surface of the gate insulating film are terminated with nitrogen atoms and almost all dangling bonds on a bottom surface of the gate insulating film contacting the silicon substrate are terminated with fluorine atoms.

The method of manufacturing a semiconductor device according to the present invention includes: a first step of forming a gate insulating filmon a silicon substrate; a second step of terminating dangling bonds on a surface of the gate insulating film and an interface between the silicon substrate and the gate insulating film with fluorine atoms; a third step of forming new dangling bonds on the surface of the gate insulating film; and a fourth step of terminating the new dangling bonds with nitrogen atoms.

According to the present invention, because the dangling bonds on the surface (top surface) of the gate insulating film are terminated with nitrogen atoms, boron leakage from the gate electrode is suppressed sufficiently. As almost all dangling bonds on the interface between the gate insulating film and the silicon substrate are terminated with fluorine atoms, an increase in interface state density and generation of plus charge in the gate insulating film are suppressed sufficiently. The dangling bonds on the interface between the gate insulating film and the silicon substrate are terminated with fluorine atoms before the surface of the gate insulating film is terminated with nitrogen atoms. The entire bottom surface is thus terminated with fluorine atoms.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a partial cross-sectional view of configuration of a semiconductor device according to an embodiment of the present invention;

FIG. 2 shows a process (forming a silicon oxide film 11o) in a method of manufacturing the semiconductor memory device according to the present embodiment;

FIG. 3 shows a process (performing thermally treatment under an organic fluorine gas) in a method of manufacturing the semiconductor memory device according to the present embodiment;

FIG. 4 shows a process (forming a silicon oxide film 11f) in a method of manufacturing the semiconductor memory device according to the present embodiment;

FIG. 5 shows a process (forming new silicon dangling bonds 16) in a method of manufacturing the semiconductor memory device according to the present embodiment;

FIG. 6 shows a process (cutting Si—O bindings in the surface 11a of the silicon oxide film 11f) in a method of manufacturing the semiconductor memory device according to the present embodiment;

FIG. 7 shows a process (forming silicon dangling bonds 18) in a method of manufacturing the semiconductor memory device according to the present embodiment;

FIG. 8 shows a process (performing a plasma nitriding treatment) in a method of manufacturing the semiconductor memory device according to the present embodiment;

FIG. 9 shows a process (forming a gate insulating film 11 that is made of the silicon oxide film containing nitrogen and fluorine) in a method of manufacturing the semiconductor memory device according to the present embodiment;

FIG. 10 is a graph showing the amount of nitrogen from the surface of the gate insulating film 11 toward the silicon substrate 10 in the state of FIG. 9; and

FIG. 11 is a graph showing the amount of nitrogen from the surface of the gate insulating film 11 toward the silicon substrate 10 in the state of FIG. 1.

### DETAILED DESCRIPTION OF THE EMBODIMENTS

Preferred embodiments of the present invention will be explained below in detail with reference to the accompanying drawings.

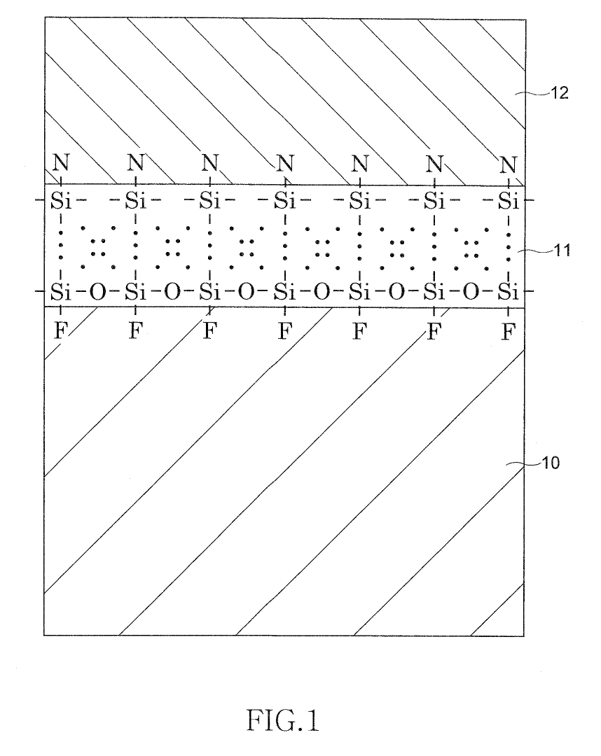

FIG. 1 is a partial cross-sectional view of configuration of a semiconductor device according to an embodiment of the present invention.

As shown in FIG. 1, a gate insulating film 11 is formed on a silicon substrate 10. On the gate insulating film 11, a gate electrode 12 made of polysilicon containing boron (B) is formed.

The gate insulating film 11 contains silicon (Si) atoms, oxygen (O) atoms, nitrogen (N) atoms, and fluorine (F) atoms. Almost all silicon dangling bonds on a surface (top surface) of the gate insulating film 11 are terminated with nitrogen atoms. Almost all silicon dangling bonds on a bottom surface of the gate insulating film 11 contacting the silicon substrate 10 are terminated with fluorine atoms.

Because of the above configuration, even if a thermal load obtained when, for example, the semiconductor device is held at about 1000° C. for 10 seconds and then at about 800° C. for 30 minutes under an N₂ atmosphere is applied during the steps of forming the semiconductor device after the gate electrode 12 is formed, boron leakage from the gate electrode 12 is suppressed because the dangling bonds on the surface (top surface) of the gate insulating film 11 are terminated with nitrogen atoms.

Almost all silicon dangling bonds on the bottom surface of the gate insulating film 11 contacting the silicon substrate 10 are terminated with fluorine atoms. Such termination with fluorine atoms allows for resistance to high temperature thermal loads. An Si—F binding energy (≈130 kcal/mol) produced on the interface between the gate insulating film 11 and the silicon substrate 10 is larger than an Si—N binding energy (105 kcal/mol) produced on the surface of the gate insulating film 11. Even if the aforementioned thermal load is applied so that a part of the nitrogen atoms on the surface of the gate insulating film 11 is moved toward the silicon substrate 10, a nitrogen layer is hardly formed at the interface between the gate insulating film 11 and the silicon substrate 10 because the Si—F binding is held at more stable state than the Si—N binding. An increase in interface state density and generation of plus charge in the gate insulating film are thus suppressed.

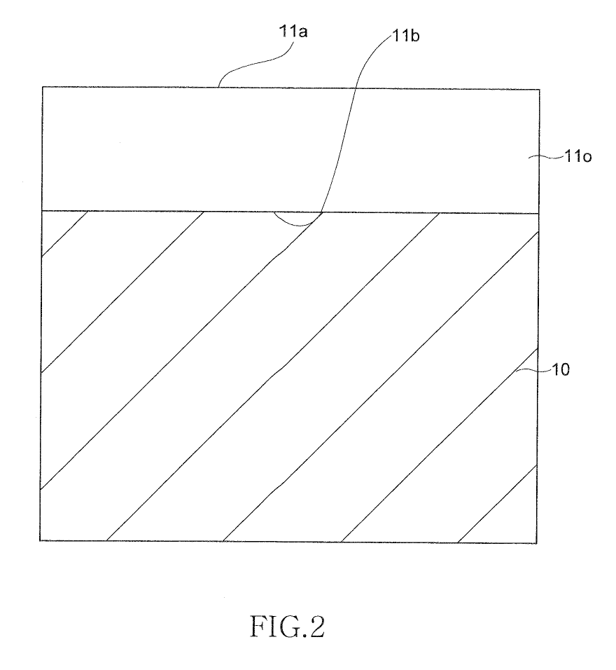

A manufacturing method of the semiconductor device according to the present embodiment will be described next. FIGS. 2 to 9 are partial cross-sectional views of the manufacturing method according to the present embodiment arranged in the order of steps.

As shown in FIG. 2, the surface of the silicon substrate 10 is thermally oxidized to form, on the silicon substrate 10, a silicon oxide film 11o that has a top surface (surface) 11a and a bottom surface (rear surface) 11b serving as the interface with the silicon substrate 10. The thickness of the silicon oxide film 11o is preferably about 5 to 7 nm.

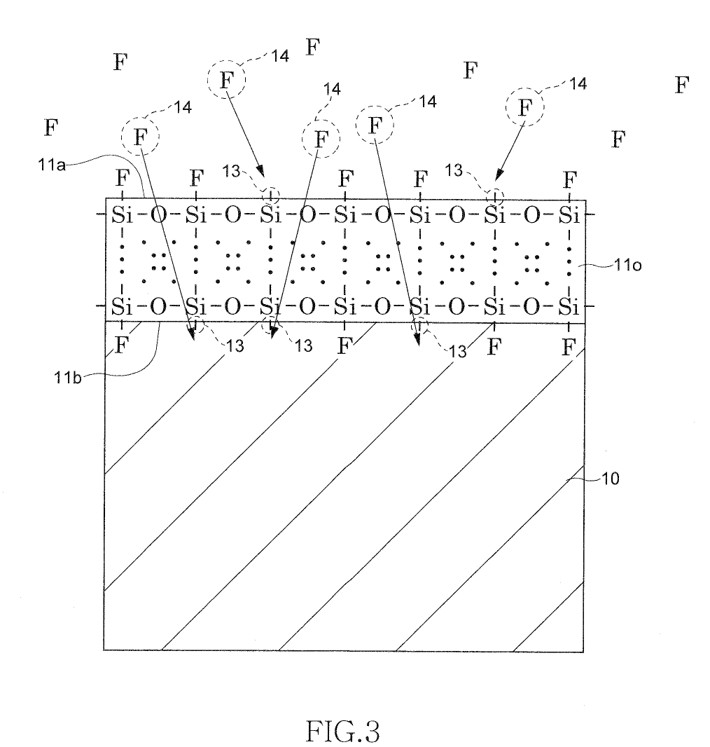

As shown in FIG. 3, the silicon substrate 10 with the silicon oxide film 11o formed on its surface is thermally treated under an organic fluorine gas (fluorine gas, fluoromethane gas, fluorocarbon gas, etc.) atmosphere at 400 to 600° C. for 1 to 2 hours. Silicon dangling bonds 13 on the surface 11a and the rear surface 11b of the silicon oxide film 11o contacting the silicon substrate 10 are terminated with fluorine atoms (F) 14. If the dangling bonds 13 are terminated using the organic fluorine gas, the damage of the silicon oxide film 11o is minimized.

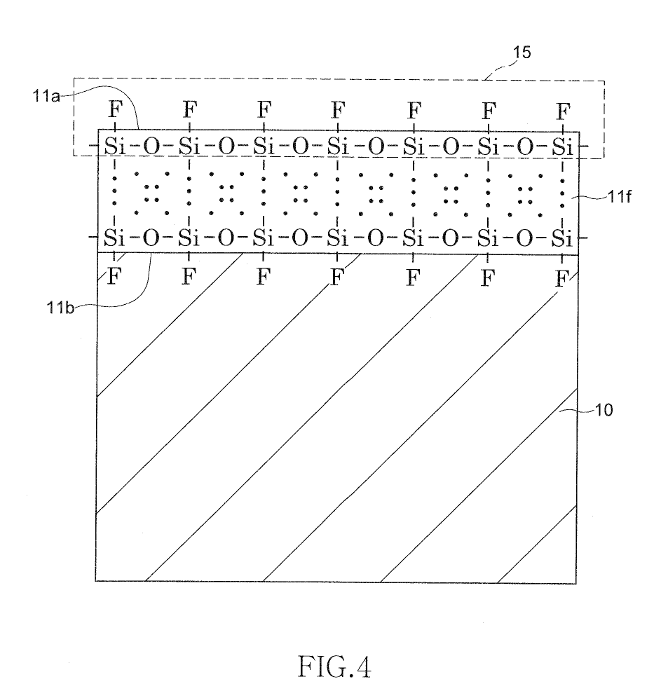

As shown in FIG. 4, a silicon oxide film 11f containing fluorine is formed that the silicon dangling bonds on the surface 11a and the rear surface 11b are terminated with fluorine atoms.

The silicon dangling bond can be terminated with the fluorine atom by fluorine ion implantation instead of the above-described thermal treatment with the organic fluorine gas. The ion implantation enables easy depth control and increased implantation amount. Although the gate insulating film may be damaged during the ion implantation, it is recovered from the damage by thermally treated under a nitrogen gas atmosphere.

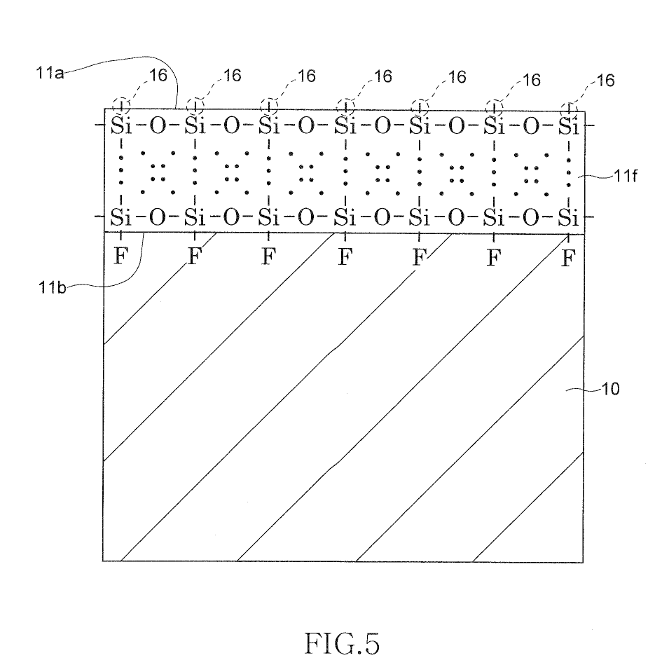

As shown in FIG. 4, the surface 11a of the silicon oxide film 11f containing fluorine is immersed in a fluoric acid solution 15. A surface layer of the silicon oxide film 11f damaged during prior steps is wet etched so that a clean surface is exposed. As shown in FIG. 5, silicon dangling bonds 16 are newly formed on the surface 11a of the silicon oxide film 11f. The thickness of the silicon oxide film 11f is about 1.2 to 2.0 nm as a result of the wet etching. By removing the surface layer using the fluoric acid solution 15, a less damaged silicon oxide film 11f can be formed, and different atoms are not mixed in the silicon oxide film 11f.

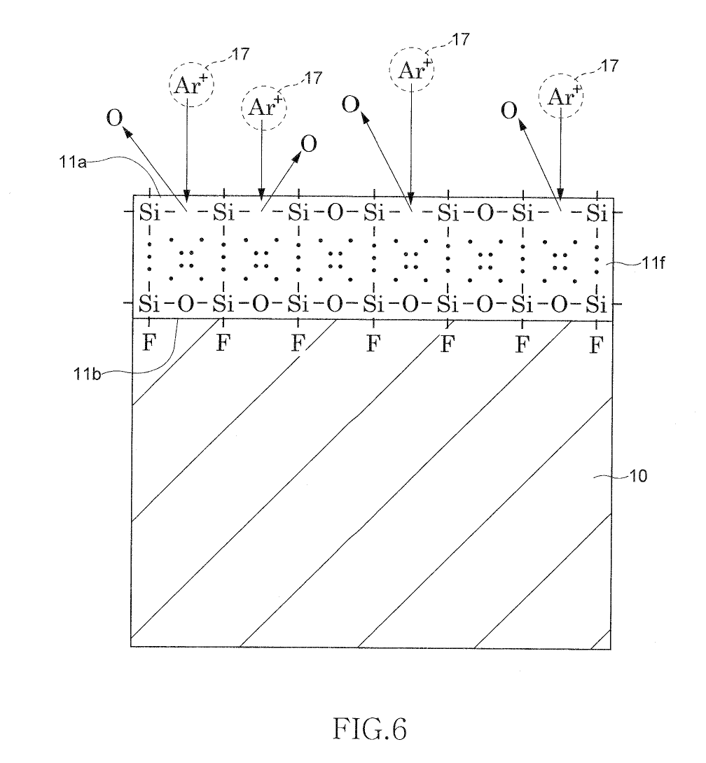

As shown in FIG. 6, Ar ions 17 are implanted as an inert gas in the surface 11a of the silicon oxide film 11f to cut Si—O bindings thereon. For the ion implantation, the implantation energy is preferably about 1 KeV and the dosed amount about 1.0×10¹³/cm² to 1.0×10¹⁵/cm².

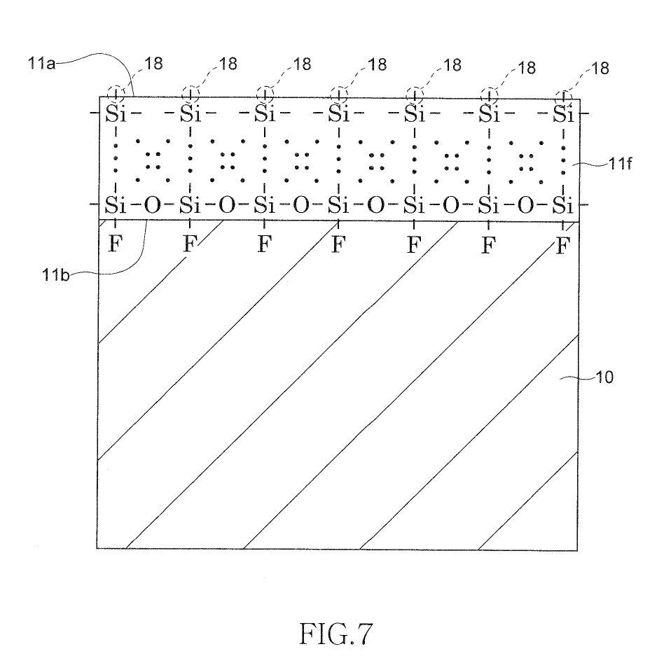

As shown in FIG. 7, silicon dangling bonds 18 with higher reactivity to nitrogen active species N* as compared to the state of FIG. 5 are formed at the silicon oxide film 11f.

In addition to Ar, rare gas ions such as He, Ne, and Xe are used as inert gas ions for cutting the Si—O binding. If the dangling bond 18 is formed by implanting rare gas ions, different atoms are not mixed in the silicon oxide film 11f.

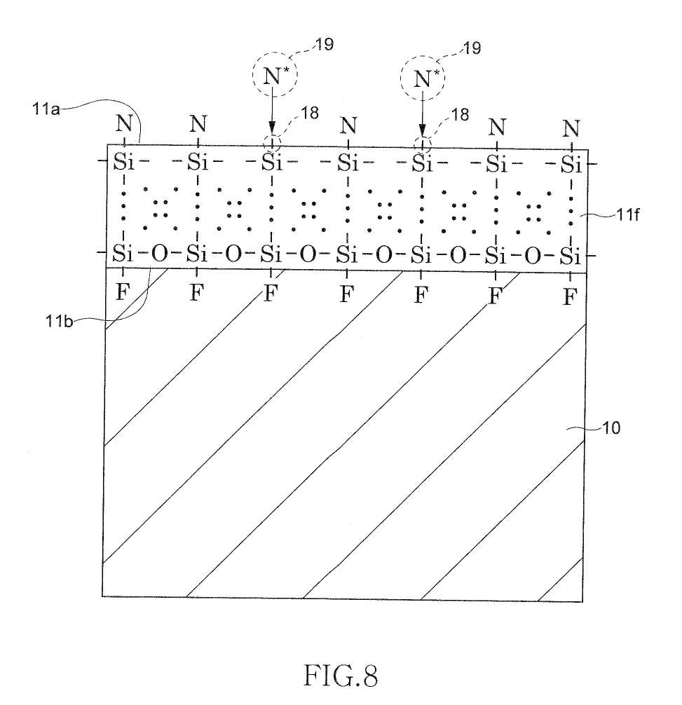

As shown in FIG. 8, a plasma nitriding treatment is performed upon the surface 11a of the silicon oxide film 11f using a nitrogen active species 19 (N*). Nitrogen atoms are thus adsorbed to the silicon dangling bonds 18. In the plasma nitriding treatment, about 10 to 20 atomic weight percent of nitrogen with respect to the amount of oxygen contained in the silicon oxide film 11f is preferably introduced.

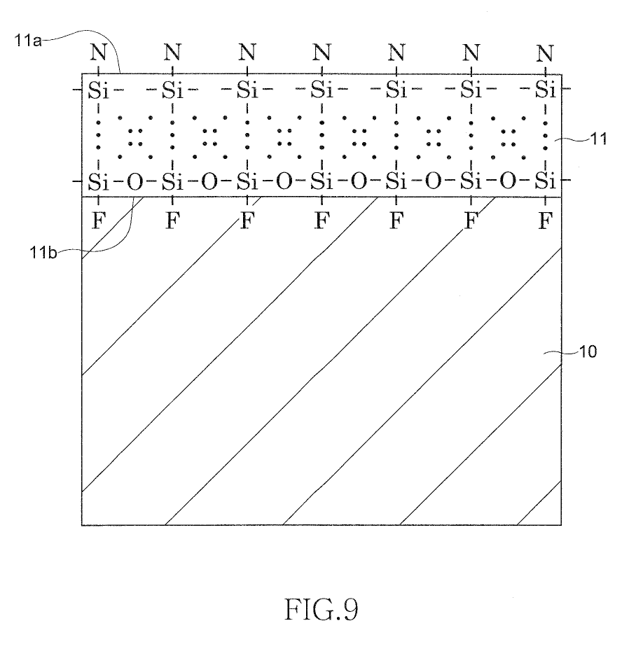

As shown in FIG. 9, the gate insulating film 11 that is made of the silicon oxide film containing nitrogen and fluorine whose surface 11a is terminated with nitrogen atoms and whose rear surface 11b is terminated with fluorine atoms is thus completed. Dangling bonds included in the gate insulating film 11 have been terminated when the gate electrode 12 is formed.

As shown in FIG. 1, the gate electrode 12 made of a polysilicon film containing boron (B) is then formed on the gate insulating film 11. Because the dangling bonds included in the gate insulating film 11 have been terminated, fluorine ions need not to be implanted via the gate electrode 12.

Thereafter, although not shown in the drawings, source/drain regions and various electrodes are then formed by normal methods, and a MOS transistor is thus completed.

According to the present embodiment, the both surfaces of the gate insulating film are terminated with fluorine atoms and newly formed dangling bonds on the surface of the gate insulating film are then terminated with nitrogen atoms. Almost all dangling bonds on the top surface of the gate insulating film are terminated with nitrogen atoms and almost all dangling bonds on the bottom surface of the gate insulating film are terminated with fluorine atoms. Accordingly, even if the gate insulating film is thin, boron leakage from the gate electrode is suppressed sufficiently. An increase in interface state density and generation of plus charge in the gate insulating film are suppressed. Because the gate insulating film 11 has been terminated at the time of forming the gate electrode 12, fluorine ions need not to be implanted via the gate electrode 12.

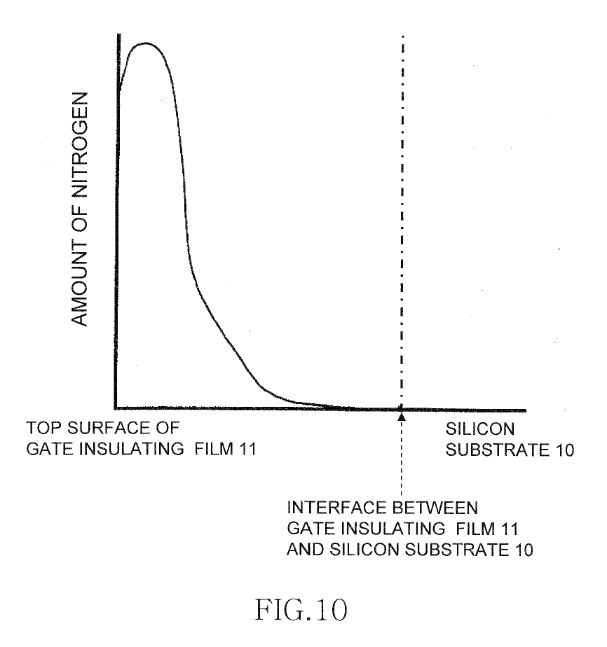

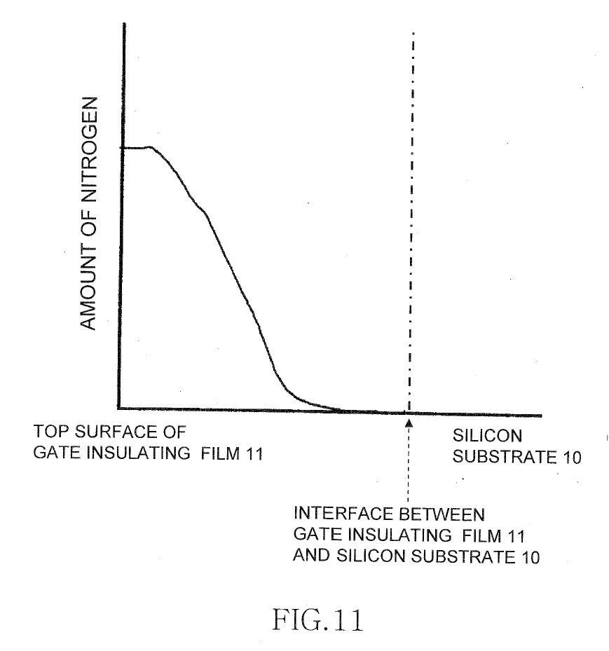

Effects of the present embodiment will be described in detail with reference to FIGS. 10 and 11.

FIG. 10 is a graph showing the amount of nitrogen from the surface of the gate insulating film 11 toward the silicon substrate 10 in the state of FIG. 9, i.e., after the plasma nitriding treatment.

FIG. 11 is a graph showing the amount of nitrogen from the surface of the gate insulating film 11 toward the silicon substrate 10 after a thermal treatment that the semiconductor device is held, e.g., at about 1000° C. for 10 seconds and at about 800° C. for 30 minutes under an N₂ atmosphere, which is provided by converting a thermal load applied during the steps of forming the device after the gate electrode 12 shown in FIG. 1 is formed.

FIGS. 10 and 11 are graphs when EOT of the gate insulating film 11 is 2.0 nm.

As can be understood from FIG. 10, most nitrogen atoms exist near the surface of the gate insulating film 11. Few nitrogen atoms exist near the interface between the gate insulating film 11 and the silicon substrate 10.

Meanwhile, as shown in FIG. 11, although nitrogen spreads in the depth direction of the gate insulating film, it remains sufficiently near the surface of the gate insulating film 11. That is, the entire surface of the gate insulating film 11 is almost terminated with nitrogen atoms. While a thermal load is applied near the interface between the gate insulating film 11 and the silicon substrate 10, few nitrogen atoms exist as is the case with FIG. 10. This is because the interface between the gate insulating film 11 and the silicon substrate 10 has been almost terminated with fluorine when the surface of the gate insulating film 11 is terminated with nitrogen atoms.

By forming the gate insulating film as described above, the semiconductor device that has the gate insulating film in which almost all dangling bonds on the top surface are terminated with nitrogen atoms and almost all dangling bonds on the bottom surface contacting the silicon substrate are terminated with fluorine atoms can be formed.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

While the silicon oxide film is formed in the step shown in FIG. 2 according to the embodiment of the manufacturing method, other insulating films can be used. For example, an HfSiO₂ film (HfSiOₓ film) and high dielectric metal oxide films can be used.

If the HfO₂ film (HfSiOₓ film) is used, hafnium dangling bonds and silicon dangling bonds are formed during manufacturing of the device. If high dielectric metal oxide films are used, metallic dangling bonds are formed. Such dangling bonds are terminated with fluorine atoms on the bottom surface of the gate insulating film and with nitrogen atoms on the top surface.

Films containing at least one of, e.g., ZrO₂, TiO₂, Al₂O₃, Nb₂O₅, Ta₂O₅, La₂O₃, SrTiO₃, PbTiO₃ (Sr, Ba) TiO₃, and Pb (Zr, Ti)O are used for the high dielectric metal oxide film. Such films are formed by ALD (Atomic Layer Deposition) or MOCVD (Metal-Organic Chemical Vapor Deposition).

What is claimed is:

1. A semiconductor device comprising:
a silicon substrate; and
a gate insulating film formed on the silicon substrate, wherein
dangling bonds on a top surface of the gate insulating film are terminated with nitrogen atoms and dangling bonds on a bottom surface of the gate insulating film contacting the silicon substrate are terminated with fluorine atoms.

2. The semiconductor device as claimed in claim 1, wherein the gate insulating film is etched.

3. A manufacturing method of a semiconductor device comprising:
a first step of forming a gate insulating film on a silicon substrate;
a second step of terminating dangling bonds on a top surface of the gate insulating film and an interface between the silicon substrate and the gate insulating film with fluorine atoms;
a third step of forming new dangling bonds on the top surface of the gate insulating film; and
a fourth step of terminating the new dangling bonds with nitrogen atoms.

4. The manufacturing method of a semiconductor device as claimed in claim 3, wherein the second step is performed by thermally treating the silicon substrate in an atmosphere of fluorine gas, fluoromethane gas, or fluorocarbon gas.

5. The manufacturing method of a semiconductor device as claimed in claim 3, wherein the second step is performed by implanting fluorine ions in the gate insulating film.

6. The manufacturing method of a semiconductor device as claimed in claim 3, wherein the third step comprising:
a first sub-step of removing a top surface layer on the top surface of the gate insulating film; and
a second sub-step of cutting binding of an oxygen atom and an atom which is different from the oxygen atom on the top surface of the gate insulating film.

7. The manufacturing method of a semiconductor device as claimed in claim 6, wherein the first sub-step is performed by wet etching the top surface of the gate insulating film with a fluoric acid solution.

8. The manufacturing method of a semiconductor device as claimed in claim 6, wherein the second sub-step is performed by implanting inert gas ions in the top surface of the gate insulating film.

9. The manufacturing method of a semiconductor device as claimed in claim 3, further comprising a fifth step of forming a gate electrode on the gate insulating film after performing the fourth step.

10. A manufacturing method of a semiconductor device comprising a first step of forming a gate insulating film having top and bottom surfaces on a silicon substrate, and a second step of etching the top surface to reduce thickness of the gate insulating film, wherein
dangling bonds on the bottom surface of the gate insulating film are terminated with fluorine atoms prior to the second step, and
dangling bonds on the top surface of the gate insulating film are terminated with nitrogen atoms after the seconds step.
